(19) United States
(12) Patent Application Publication
(10) Pub. No.: US 2020/0211874 A1
(43) Pub. Date: Jul. 2, 2020

(54) APPARATUS AND METHOD FOR TREATING SUBSTRATE

(71) Applicant: SEMES CO., LTD., Cheonan-si (KR)

(72) Inventors: Sung Yong LEE, Anyang-si (KR); Donghyuk SEO, Cheonan-si (KR); Sangbok HAN, Asan-si (KR); Tae Sub LEE, Seoul (KR)

(73) Assignee: SEMES CO., LTD., Cheonan-si (KR)

(21) Appl. No.: 16/726,293

(22) Filed: Dec. 24, 2019

(30) Foreign Application Priority Data
Dec. 28, 2018 (KR) 10-2018-0172668

(51) Int. Cl. H01L 21/67; H01L 21/324; H01L 21/66; G03F 7/20

(52) U.S. Cl. CPC H01L 21/67248; H01L 21/67109; G03F 7/70858; H01L 22/26; H01L 21/324

(57) ABSTRACT

Disclosed is a substrate treating apparatus that includes a housing having a process space therein, a plate that supports a substrate in the housing, a heating member that is provided in the plate and that heats the substrate, a plurality of controllers that control the heating member and that have different gains, a temperature measurement member that measures temperature in the housing, and a control member that switches the plurality of controllers to cause one of the plurality of controllers to control the heating member depending on a temperature drop section, a temperature rise section, and an anneal section in the housing.

### CROSS-REFERENCE TO RELATED APPLICATIONS

A claim for priority under 35 U.S.C. § 119 is made to Korean Patent Application No. 10-2018-0172668 filed on Dec. 28, 2018, in the Korean Intellectual Property Office, the entire contents of which are hereby incorporated by reference.

### BACKGROUND

Embodiments of the inventive concept described herein relate to an apparatus and method for treating a substrate, and more particularly, relate to a substrate treating apparatus and method for controlling a substrate heating member by adjusting a gain of a controller.

Various processes, such as photolithography, etching, deposition, ion implantation, cleaning, and the like, are performed to manufacture semiconductor elements. Among these processes, the photolithography process for forming a pattern plays an important role in achieving high density integration of the semiconductor elements.

The photolithography process includes a coating process, an exposing process, and a developing process, and a bake process is performed before and after the exposing process. The bake process is a process of performing heat treatment on a substrate. When the substrate is placed on a heating plate, the heat treatment is performed on the substrate through a heating member provided in the heating plate.

In general, a PID controller is used to control the heating member. In the related art, the heating member is controlled by using a PID controller having one PID gain. In the bake process, the temperature in a housing has a temperature drop section, a temperature rise section, and an anneal section. In the case of controlling the heating member using the PID controller having one PID gain, temperature oscillation may occur, and temperature hunting may occur at the time point (the inflection point) at which the temperature section in the housing changes.

### SUMMARY

Embodiments of the inventive concept provide a substrate treating apparatus and method for controlling a substrate heating member by changing a gain of a controller depending on temperature sections in a housing.

According to an exemplary embodiment, an apparatus for treating a substrate includes a housing having a process space therein, a plate that supports the substrate in the housing, a heating member that is provided in the plate and that heats the substrate, a plurality of controllers that control the heating member and that have different gains, a temperature measurement member that measures temperature in the housing, and a control member that switches the plurality of controllers to cause one of the plurality of controllers to control the heating member depending on a temperature drop section, a temperature rise section, and an anneal section in the housing.

The plurality of controllers may be a plurality of PID controllers having different PID gains.

In the temperature drop section, the control member may connect a PID controller having a relatively high P gain, among the plurality of PID controllers, to the heating member.

In the temperature rise section, the control member may connect a PID controller having a relatively high P gain, among the plurality of PID controllers, to the heating member.

In the anneal section, the control member may connect a PID controller having a relatively high I gain, among the plurality of PID controllers, to the heating member.

In the anneal section, the control member may connect a PID controller having a relatively high D gain, among the plurality of PID controllers, to the heating member.

The control member may determine the temperature drop section, the temperature rise section, and the anneal section by using a slope of temperature variation measured by the temperature measurement member.

The control member may determine the temperature drop section when the slope of temperature variation is below a preset range, may determine the temperature rise section when the slope of temperature variation is above the preset range, and may determine the anneal section when the slope of temperature variation is within the preset range.

According to an exemplary embodiment, a bake apparatus includes a housing having a process space therein, a plate that supports a substrate in the housing, a heating member that is provided in the plate and that heats the substrate, a plurality of PID controllers that control the heating member and that have different PID gains, a temperature measurement member that measures temperature in the housing, and a control member that connects a PID controller having a relatively high P gain, among the plurality of PID controllers, to the heating member in a temperature drop section and a temperature rise section in the housing and connects a PID controller having a relatively high I or D gain, among the plurality of PID controllers, to the heating member in an anneal section in the housing.

The control member may determine the temperature drop section, the temperature rise section, and the anneal section by using a reference profile stored in advance.

The control member may determine the temperature drop section when a slope of temperature variation is below a preset range, may determine the temperature rise section when the slope of temperature variation is above the preset range, and may determine the anneal section when the slope of temperature variation is within the preset range.

According to an exemplary embodiment, a method for treating a substrate by controlling a heating member provided in a plate for supporting the substrate in a housing includes measuring temperature in the housing and switching a plurality of controllers having different gains to cause one of the plurality of controllers to control the heating member depending on a temperature drop section, a temperature rise section, and an anneal section in the housing.

The plurality of controllers may be a plurality of PID controllers having different PID gains.

In the temperature drop section, a PID controller having a relatively high P gain, among the plurality of PID controllers, may be connected to the heating member.

In the temperature rise section, a PID controller having a relatively high P gain, among the plurality of PID controllers, may be connected to the heating member.

In the anneal section, a PID controller having a relatively high I gain, among the plurality of PID controllers, may be connected to the heating member.

In the anneal section, a PID controller having a relatively high D gain, among the plurality of PID controllers, may be connected to the heating member.

The temperature drop section, the temperature rise section, and the anneal section in the housing may be determined by using a slope of temperature variation in the housing.

The temperature drop section may be determined when the slope of temperature variation is below a preset range, the temperature rise section may be determined when the slope of temperature variation is above the preset range, and the anneal section may be determined when the slope of temperature variation is within the preset range.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view of a substrate treating apparatus as viewed from above;

FIG. 2 is a view illustrating the substrate treating apparatus of FIG. 1 when viewed in direction A-A;

FIG. 3 is a view illustrating the substrate treating apparatus of FIG. 1 when viewed in direction B-B;

FIG. 4 is a view illustrating the substrate treating apparatus of FIG. 1 when viewed in direction C-C;

FIG. 5 is a plan view illustrating a bake unit according to an embodiment of the inventive concept;

FIG. 6 is a sectional view illustrating a substrate treating apparatus for performing a heating process according to an embodiment of the inventive concept;

FIGS. 7 to 9 are views illustrating temperature variation sections in a housing according to an embodiment of the inventive concept; and

FIG. 10 is a flowchart illustrating a substrate treating method according to an embodiment of the inventive concept.

### DETAILED DESCRIPTION

Hereinafter, embodiments of the inventive concept will be described in more detail with reference to the accompanying drawings. Various modifications and variations can be made to the embodiments of the inventive concept, and the scope of the inventive concept should not be construed as limited to the embodiments set forth herein. These embodiments are provided so that the inventive concept will be thorough and complete, and will fully convey the scope of the inventive concept to those skilled in the art. Accordingly, in the drawings, the shapes of components are exaggerated for clarity of illustration.

Equipment according to this embodiment may be used to perform a photolithography process on a substrate such as a semiconductor wafer or a flat display panel. In particular, the equipment according to this embodiment may be connected to a stepper and may be used to perform a coating process and a developing process on a substrate. In the following description, it will be exemplified that a wafer is used as a substrate.

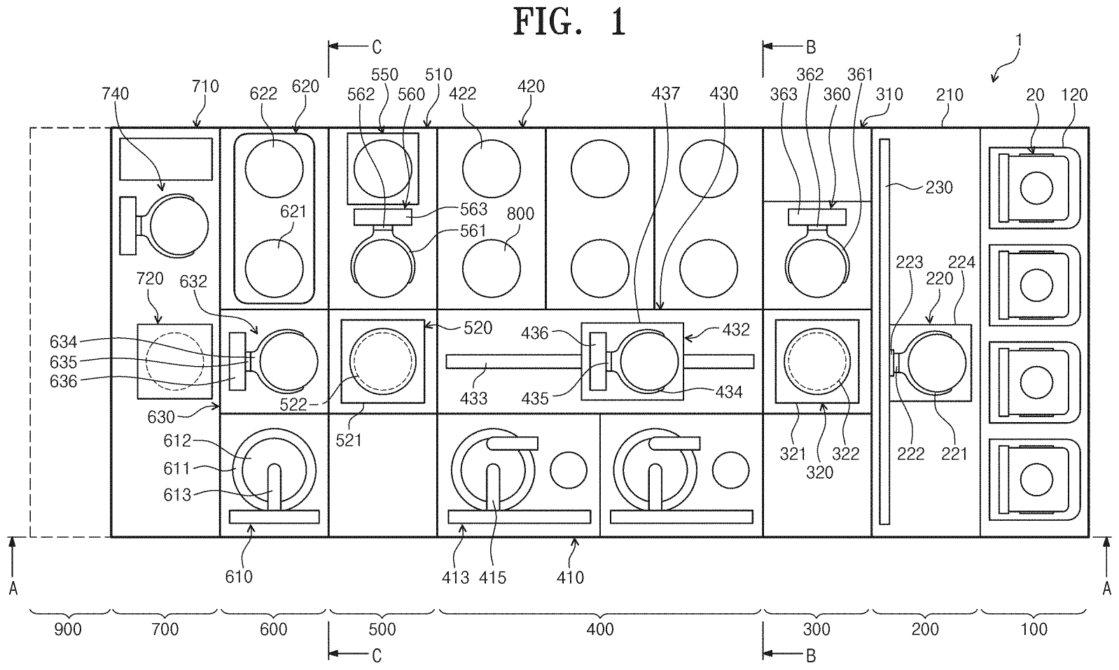

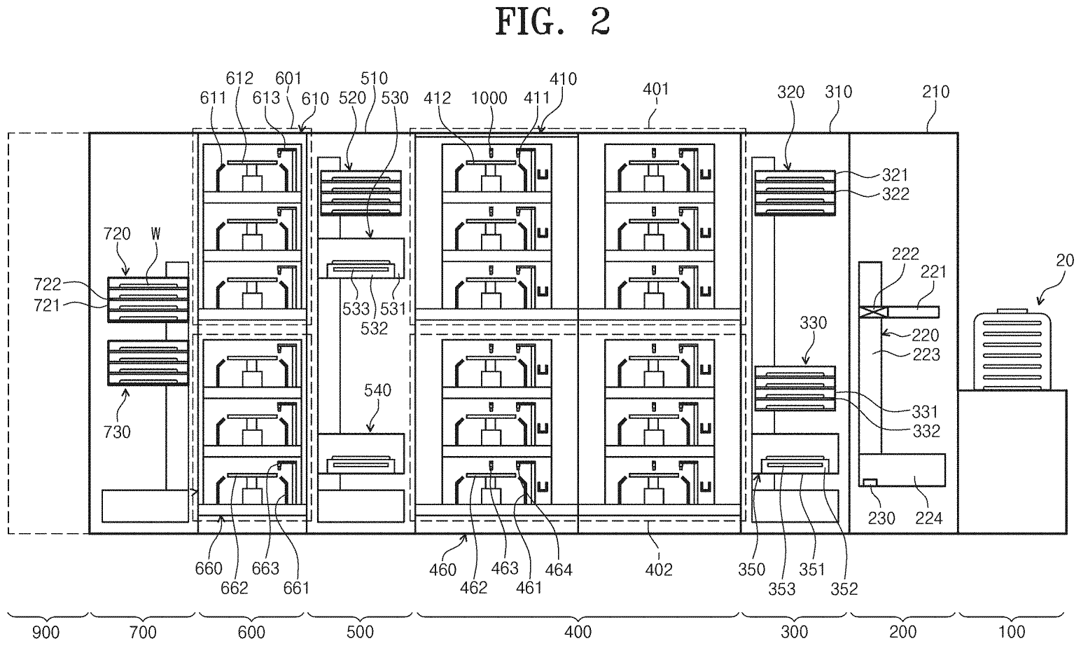

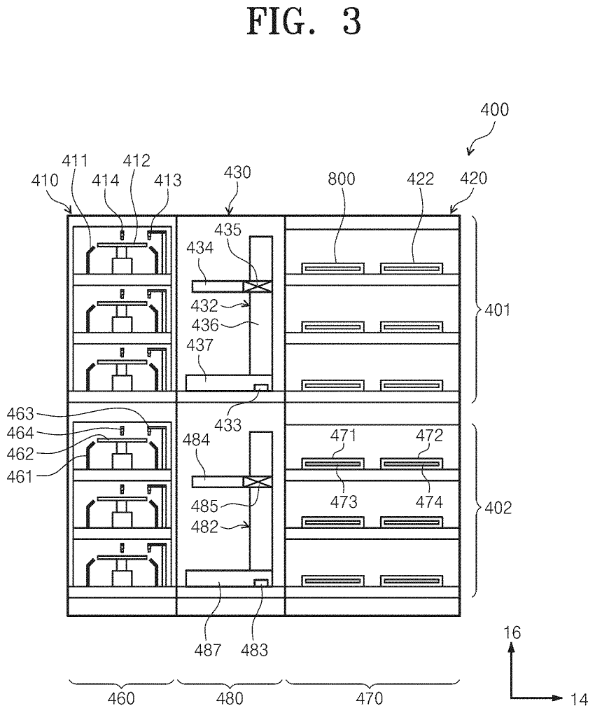

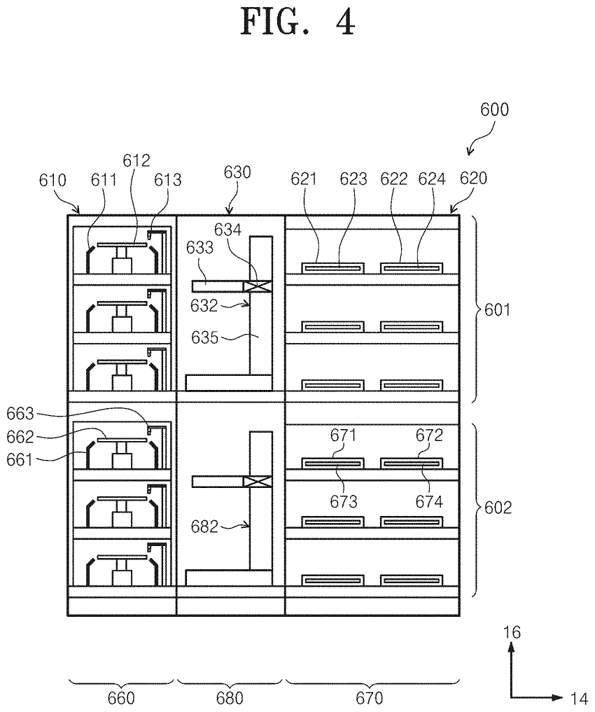

FIGS. 1 to 4 are schematic views illustrating substrate treating equipment according to an embodiment of the inventive concept.

Referring to FIGS. 1 to 4, the substrate treating equipment 1 includes a load port 100, an index module 200, a first buffer module 300, a coating and developing module 400, a second buffer module 500, a pre/post-exposure process module 600, and an interface module 700. The load port 100, the index module 200, the first buffer module 300, the coating and developing module 400, the second buffer module 500, the pre/post-exposure process module 600, and the interface module 700 are sequentially arranged in a row in one direction.

Hereinafter, the direction in which the load port 100, the index module 200, the first buffer module 300, the coating and developing module 400, the second buffer module 500, the pre/post-exposure process module 600, and the interface module 700 are arranged is referred to as a first direction 12. A direction perpendicular to the first direction 12 when viewed from above is referred to as a second direction 14, and a direction perpendicular to the first direction 12 and the second direction 14 is referred to as a third direction 16.

Substrates W are moved in a state of being received in cassettes 20. The cassettes 20 have a structure that can be sealed from the outside. For example, front open unified pods (FOUPs), each of which has a door at the front, may be used as the cassettes 20.

Hereinafter, the load port 100, the index module 200, the first buffer module 300, the coating and developing module 400, the second buffer module 500, the pre/post-exposure process module 600, and the interface module 700 will be described in detail.

The load port 100 includes mounting tables 120 on which the cassettes 20, each of which has the substrates W received therein, are placed. The mounting tables 120 are arranged in a row along the second direction 14. In FIG. 1, four mounting tables 120 are provided.

The index module 200 transfers the substrates W between the cassettes 20 placed on the mounting tables 120 of the load port 100 and the first buffer module 300. The index module 200 includes a frame 210, an index robot 220, and a guide rail 230. The frame 210 has a substantially rectangular parallelepiped shape with an empty space inside and is disposed between the load port 100 and the first buffer module 300. The frame 210 of the index module 200 may be located in a lower position than a frame 310 of the first buffer module 300 that will be described below. The index robot 220 and the guide rail 230 are disposed in the frame 210. The index robot 220 has a structure capable of 4-axis driving such that a hand 221 directly handling the substrates W is movable in the first direction 12, the second direction 14, and the third direction 16 and is rotatable. The index robot 220 includes the hand 221, an arm 222, a support rod 223, and a base 224. The hand 221 is fixedly attached to the arm 222. The arm 222 is provided in a retractable and rotatable structure. The support rod 223 is arranged such that the lengthwise direction thereof is parallel to the third direction 16. The arm 222 is coupled to the support rod 223 so as to be movable along the support rod 223. The support rod 223 is fixedly coupled to the base 224. The guide rail 230 is arranged such that the lengthwise direction thereof is parallel to the second direction 14. The base 224 is coupled to the guide rail 230 so as to be rectilinearly movable along the guide rail 230. Furthermore, although not illustrated, a door opener for opening/closing the doors of the cassettes 20 is additionally provided in the frame 210.

The first buffer module 300 includes the frame 310, a first buffer 320, a second buffer 330, a cooling chamber 350, and a first buffer robot 360. The frame 310 has a rectangular parallelepiped shape with an empty space inside and is disposed between the index module 200 and the coating and developing module 400. The first buffer 320, the second buffer 330, the cooling chamber 350, and the first buffer robot 360 are located in the frame 310. The cooling chamber 350, the second buffer 330, and the first buffer 320 are sequentially arranged along the third direction 16 from bottom to top. The first buffer 320 is located at the height corresponding to a coating module 401 of the coating and developing module 400 that will be described below, and the second buffer 330 and the cooling chamber 350 are located at the height corresponding to a developing module 402 of the coating and developing module 400 that will be described below. The first buffer robot 360 is located to be spaced a predetermined distance apart from the second buffer 330, the cooling chamber 350, and the first buffer 320 in the second direction 14.

Each of the first buffer 320 and the second buffer 330 temporarily stores a plurality of substrates W. The second buffer 330 includes a housing 331 and a plurality of supports 332. The supports 332 are disposed in the housing 331 and are spaced apart from each other along the third direction 16. One substrate W is placed on each of the supports 332. The housing 331 has openings (not illustrated) that face the directions in which the index robot 220, the first buffer robot 360, and a developer robot 482 are provided, respectively, such that the index robot 220, the first buffer robot 360, and the developer robot 482 of the developing module 402, which will be described below, load the substrates W onto the supports 332 in the housing 331 or unload the substrates W from the supports 332 in the housing 331. The first buffer 320 has a structure substantially similar to that of the second buffer 330. However, a housing 321 of the first buffer 320 has openings that face the directions in which the first buffer robot 360 and a coater robot 432 located in the coating module 401 are provided, respectively. The number of supports 332 provided in the first buffer 320 may be the same as, or different from, the number of supports 332 provided in the second buffer 330. According to an embodiment, the number of supports 332 provided in the second buffer 330 may be larger than the number of supports 322 provided in the first buffer 320.

The first buffer robot 360 transfers the substrates W between the first buffer 320 and the second buffer 330. The first buffer robot 360 includes a hand 361, an arm 362, and a support rod 363. The hand 361 is fixedly attached to the arm 362. The arm 362 has a retractable structure to enable the hand 361 to move along the second direction 14. The arm 362 is coupled to the support rod 363 so as to be rectilinearly movable along the support rod 363 in the third direction 16. The support rod 363 has a length extending from the position corresponding to the second buffer 330 to the position corresponding to the first buffer 320. The support rod 363 may further extend in the upper or lower direction. The first buffer robot 360 may be provided such that the hand 361 simply performs only 2-axis driving along the second direction 14 and the third direction 16.

The cooling chamber 350 cools the substrate W. The cooling chamber 350 includes a housing 351 and a cooling plate 352. The cooling plate 352 has an upper surface on which the substrate W is placed and a cooling unit 353 that cools the substrate W. Various methods, such as cooling by cooling water, cooling using a thermoelectric element, or the like, may be used for the cooling unit 353. Furthermore, the cooling chamber 350 may include a lift pin assembly (not illustrated) that locates the substrate W on the cooling plate 352. The housing 351 has openings (not illustrated) that face the directions in which the index robot 220 and the developer robot 482 are provided, respectively, such that the index robot 220 and the developer robot 482 provided in the developing module 402 load the substrate W onto the cooling plate 352 or unload the substrate W from the cooling plate 352. In addition, the cooling chamber 350 may include doors (not illustrated) that open or close the openings described above.

The coating and developing module 400 performs a process of coating the substrate W with photoresist before an exposing process and performs a developing process on the substrate W after the exposing process. The coating and developing module 400 has a substantially rectangular parallelepiped shape. The coating and developing module 400 includes a coating module 401 and a developing module 402. The coating module 401 and the developing module 402 may be disposed on different floors so as to be divided from each other. According to an embodiment, the coating module 401 is located over the developing module 402.

The coating module 401 performs a process of coating the substrate W with a light-sensitive material such as photoresist and performs a heat treatment process, such as heating or cooling, on the substrate W before and after the photoresist coating process. The coating module 401 includes photoresist coating chambers 410, bake units 420, and a transfer chamber 430. The photoresist coating chambers 410, the bake units 420, and the transfer chamber 430 are sequentially arranged along the second direction 14. Accordingly, the photoresist coating chambers 410 and the bake units 420 are spaced apart from each other in the second direction 14, with the transfer chamber 430 therebetween. The photoresist coating chambers 410 are arranged in the first direction 12 and the third direction 16. The drawings illustrate an example that six photoresist coating chambers 410 are provided. The bake units 420 are arranged in the first direction 12 and the third direction 16. The drawings illustrate an example that six bake units 420 are provided. However, a larger number of bake units 420 may be provided.

The transfer chamber 430 is located side by side with the first buffer 320 of the first buffer module 300 in the first direction 12. The coater robot 432 and a guide rail 433 are located in the transfer chamber 430. The transfer chamber 430 has a substantially rectangular shape. The coater robot 432 transfers the substrate W between the bake units 420, the photoresist coating chambers 400, the first buffer 320 of the first buffer module 300, and a first cooling chamber 520 of the second buffer module 500 that will be described below. The guide rail 433 is arranged such that the lengthwise direction thereof is parallel to the first direction 12. The guide rail 433 guides a rectilinear movement of the coater robot 432 in the first direction 12. The transfer robot 432 includes a hand 434, an arm 435, a support rod 436, and a base 437. The hand 434 is fixedly attached to the arm 435. The arm 435 has a retractable structure to enable the hand 434 to move in the horizontal direction. The support rod 436 is arranged such that the lengthwise direction thereof is parallel to the third direction 16. The arm 435 is coupled to the support rod 436 so as to be rectilinearly movable along the support rod 463 in the third direction 16. The support rod 436 is fixedly coupled to the base 437, and the base 437 is coupled to the guide rail 433 so as to be movable along the guide rail 433.

The photoresist coating chambers 410 all have the same structure. However, the types of photoresists used in the respective photoresist coating chambers 410 may differ from one another. For example, chemical amplification resist may be used as photoresist. Each of the photoresist coating chambers 410 coats the substrate W with photoresist. The photoresist coating chamber 410 includes a housing 411, a support plate 412, and a nozzle 413. The housing 411 has a cup shape with an open top. The support plate 412 is located in the housing 411 and supports the substrate W. The support plate 412 is provided so as to be rotatable. The nozzle 413 dispenses the photoresist onto the substrate W placed on the support plate 412. The nozzle 413 may have a circular tubular shape and may dispense the photoresist onto the center of the substrate W. Selectively, the nozzle 413 may have a length corresponding to the diameter of the substrate W, and a dispensing opening of the nozzle 413 may have a slit shape. Additionally, the photoresist coating chamber 410 may further include a nozzle 414 for dispensing a cleaning solution such as deionized water to clean the surface of the substrate W that is coated with the photoresist.

The bake units 420 may perform heat treatment on the substrate W. For example, the bake units 420 perform a prebake process of removing organics or moisture on the surface of the substrate W by heating the substrate W to a predetermined temperature before the substrate W is coated with the photoresist, or perform a soft bake process after the substrate W is coated with the photoresist. In addition, the bake units 420 perform a cooling process of cooling the substrate W after the heating processes.

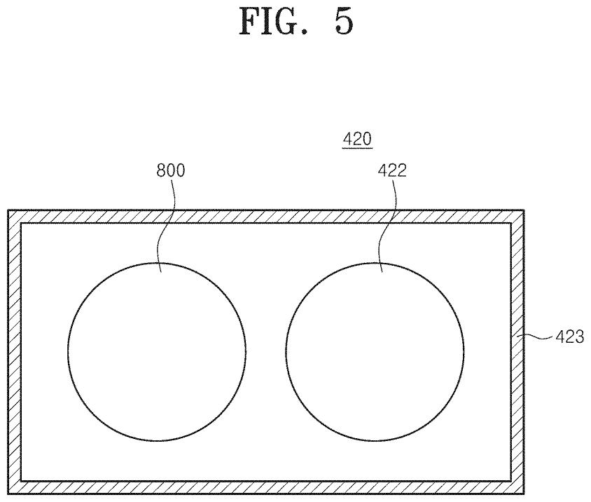

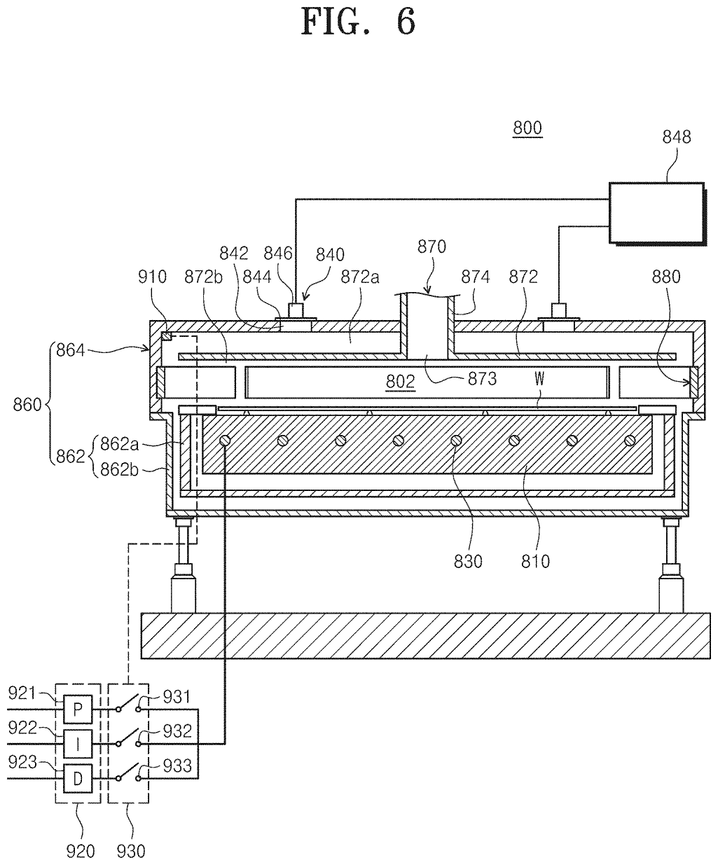

FIG. 5 is a plan view illustrating the bake unit according to an embodiment of the inventive concept. FIG. 6 is a sectional view illustrating a substrate treating apparatus for performing a heating process in the bake unit of FIG. 5.

Referring to FIGS. 5 and 6, the bake unit 420 may include a process chamber 423, a cooling plate 422, and the substrate treating apparatus 800.

The process chamber 423 has a heat treatment space therein. The process chamber 423 may have a rectangular parallelepiped shape. The cooling plate 422 may cool the substrate W heated by the substrate treating apparatus 800. The cooling plate 422 may be located in the heat treatment space. The cooling plate 422 may have a circular plate shape. A cooling means, such as cooling water or a thermoelectric element, is provided in the cooling plate 422. For example, the cooling plate 422 may cool the heated substrate W to room temperature.

The substrate treating apparatus 800 heats the substrate W. The substrate treating apparatus 800 may include a housing 860, a heating plate 810, a heating member 830, an external gas supply unit 840, a heater 880, an exhaust member 870, a temperature measurement member 910, a plurality of controllers 920, and a control member 930.

The housing 860 has a process space 802 in which a heating process is performed on the substrate W. The housing 860 includes a lower body 862, an upper body 864, and an actuator (not illustrated).

The lower body 862 may have a container shape that is open at the top. The heating plate 810 and the heating member 830 are located in the lower body 862. The lower body 862 includes double heat-insulating covers 862a and 862b to prevent thermal deformation of apparatuses around the heating plate 810. The double heat-insulating covers 862a and 862b minimize the exposure of the apparatuses around the heating plate 810 to high-temperature heat generated from the heating member 830. The double heat-insulating covers 862a and 862b include the primary heat-insulating cover 862a and the secondary heat-insulating cover 862b. The primary heat-insulating cover 862a and the secondary heat-insulating cover 862b are spaced apart from each other.

The upper body 864 has a container shape that is open at the bottom. The upper body 864 is combined with the lower body 862 to form the process space 802 inside. The upper body 864 has a larger diameter than the lower body 862. The upper body 864 is located over the lower body 862. The upper body 864 is able to be moved in the vertical direction by the actuator. The upper body 864 is able to be vertically moved between a raised position and a lowered position. Here, the raised position is a position where the upper body 864 is separated from the lower body 862, and the lowered position is a position where the upper body 864 is brought into contact with the lower body 862. In the lowered position, the gap between the upper body 864 and the lower body 862 is blocked. Accordingly, when the upper body 864 is moved to the lowered position, the process space 802 is formed by the upper body 864, the lower body 862, and the heating plate 810.

Although not illustrated, sealing members for preventing introduction of outside air into the process space 802 may be included in the housing 860. For example, the sealing members may seal the gap between the lower body 862 and the upper body 864.

The heating plate 810 is located in the process space 802. The heating plate 810 is located on one side of the cooling plate 422. The heating plate 810 has a circular plate shape. The upper surface of the heating plate 810 serves as a support area on which the substrate W is placed. The heating plate 810 has a plurality of pin holes 812 formed on the upper surface thereof. For example, three pin holes 812 may be formed on the upper surface of the heating plate 810. The pin holes 812 are located to be spaced apart from each other along the circumferential direction of the heating plate 810. The pin holes 812 are located to be spaced apart from each other at constant sections. Lift pins (not illustrated) are provided in the pin holes 812, respectively. The lift pins are able to be moved in the vertical direction by a drive member (not illustrated).

The heating member 830 heats the substrate W placed on the heating plate 810 to a preset temperature. A plurality of heating members 830 may be provided in different regions of the heating plate 810 to perform heat treatment on the substrate W for each of the regions.

The temperature measurement member 910 measures the temperature in the housing 860. The temperature measurement member 910 may be installed on an upper left side of the housing 860. However, the temperature measurement member 910 is not limited thereto. The temperature measurement member 910 measures the temperature in the housing 860 and transfers information regarding the measured temperature to the control member 930. The temperature measurement member 910 may be wiredly or wirelessly connected with the control member 930 and may transmit and receive data with the control member 930.

The plurality of controllers 920 may include controllers 921, 922, and 923 that control the heating member 830 and that have different gains. The plurality of controllers 920 may be implemented with a plurality of PID controllers having different PID gains. Furthermore, the plurality of controllers 920 may include a PID controller having a relatively high P gain, a PID controller having a relatively high I gain, and a PID controller having a relatively high D gain.

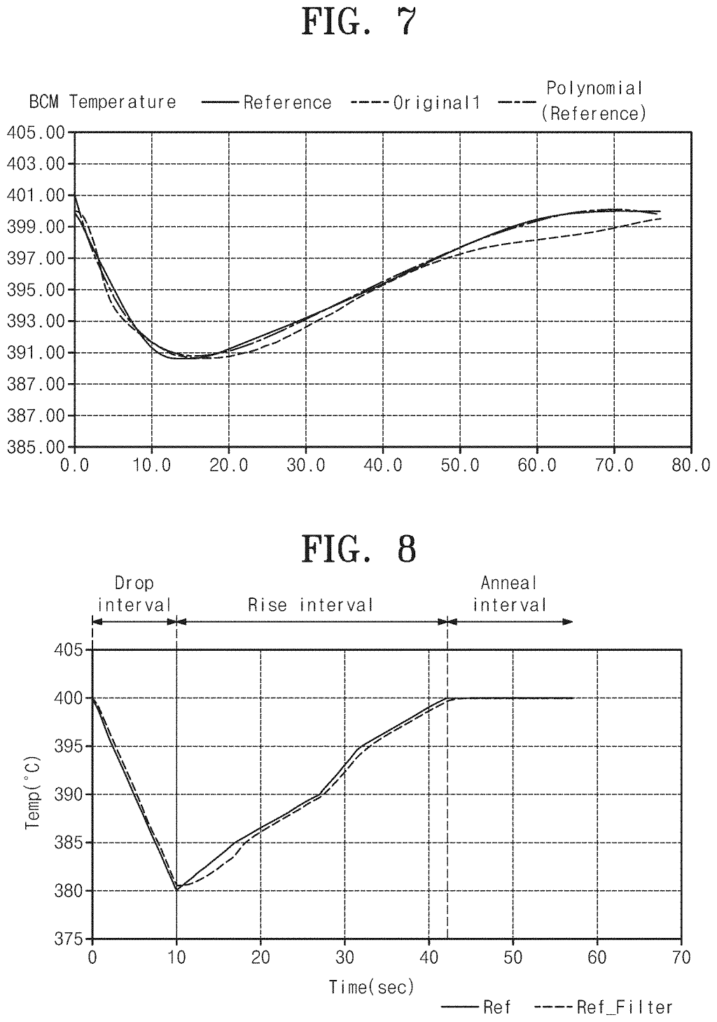

The control member 930 switches the plurality of controllers 920 to cause one of the plurality of controllers 920 to control the heating member 830, depending on a temperature drop section, a temperature rise section, and an anneal section in the housing 860. The control member 930 may be implemented with switching elements. Without being limited thereto, however, the control member 930 may be implemented with various circuits capable of connecting one of the plurality of controllers 920 to the heating member 830. A specific switching operation of the control member 930 will be described below in detail with reference to FIGS. 7 to 9.

Referring to FIG. 7, during a bake process, the temperature in the housing 860 drops for a predetermined period of time, rises again, and remains within a predetermined range from a specific time point. The section in which the temperature drops may be defined as a temperature drop section, the section in which the temperature rises may be defined as a temperature rise section, and the section in which the temperature remains within the predetermined range may be defined as an anneal section. The control member 930 according to the inventive concept may calculate a slope of temperature variation by using the temperature in the housing 860 that is measured by the temperature measurement member 910, and as illustrated in FIG. 8, the control member 930 may determine the temperature drop section, the temperature rise section, and the anneal section in the housing 860 by using the calculated slope of temperature variation. Specifically, when the slope of temperature variation in the housing 860 is below a preset range, the control member 930 may determine the corresponding section to be the temperature drop section. When the slope of temperature variation is above the preset range, the control member 930 may determine the corresponding section to be the temperature rise section. When the slope of temperature variation is within the preset range, the control member 930 may determine the corresponding section to be the anneal section. For example, in the case where the preset slope range is between −5 and +5, the section in which the slope of temperature variation calculated by using the temperature measured by the temperature measurement member 910 is less than −5 may be defined as the temperature drop section, the section in which the slope of temperature variation is more than +5 may be defined as the temperature rise section, and the section in which the slope of temperature variation ranges from −5 to +5 may be defined as the anneal section. Without being limited thereto, however, the control member 930 may determine the temperature drop section, the temperature rise section, and the anneal section by using a reference profile stored in advance.

The control member 930, after defining the temperature sections in the housing 860, may switch the PID controllers 921, 922, and 923 such that the PID controllers 921, 922, and 923 having different PID gains control the heating member 830 depending on the respective temperature sections. Referring to FIG. 9, in the temperature rise section, the control member 930 may close a first switch 931 and may open second and third switches 932 and 933 such that the PID controller 921 having a relatively high P gain, among the plurality of PID controllers 921, 922, and 923, controls the heating member 830. In the temperature rise section, an instantaneous error value is greater than those in the other sections, and therefore the heating member 830 may be stably controlled by using the PID controller 921 having a high P gain. Alternatively, in the anneal section, the control member 930 may close the second switch 932 and may open the first and third switches 931 and 933 such that the PID controller 922 having a relatively high I gain, among the plurality of PID controllers 921, 922, and 923, controls the heating member 830. In the anneal section, a cumulative error value is greater than those in the other sections, and therefore the heating member 830 may be more accurately controlled by using the PID controller 922 having a high I gain. Accordingly, the accuracy of substrate temperature control may be improved. In another case, although not illustrated in FIG. 9, in the temperature drop section, an instant error value is greater than that in the anneal section, and therefore the heating member 830 may be controlled by using the PID controller 921 having a high P gain. Accordingly, substrate temperature control may be stably performed. In another case, in the anneal section, the heating member 830 may be controlled by using the PID controller 923 having a high D gain. In this case, the control member 930 may close the third switch 933 and may open the first and second switches 931 and 932. As described above, the heating member 830 is controlled by using the PID controllers 921, 922, and 923 having different PID gains depending on the temperature sections in the housing 860. Accordingly, the substrate temperature control may be stably and accurately performed.

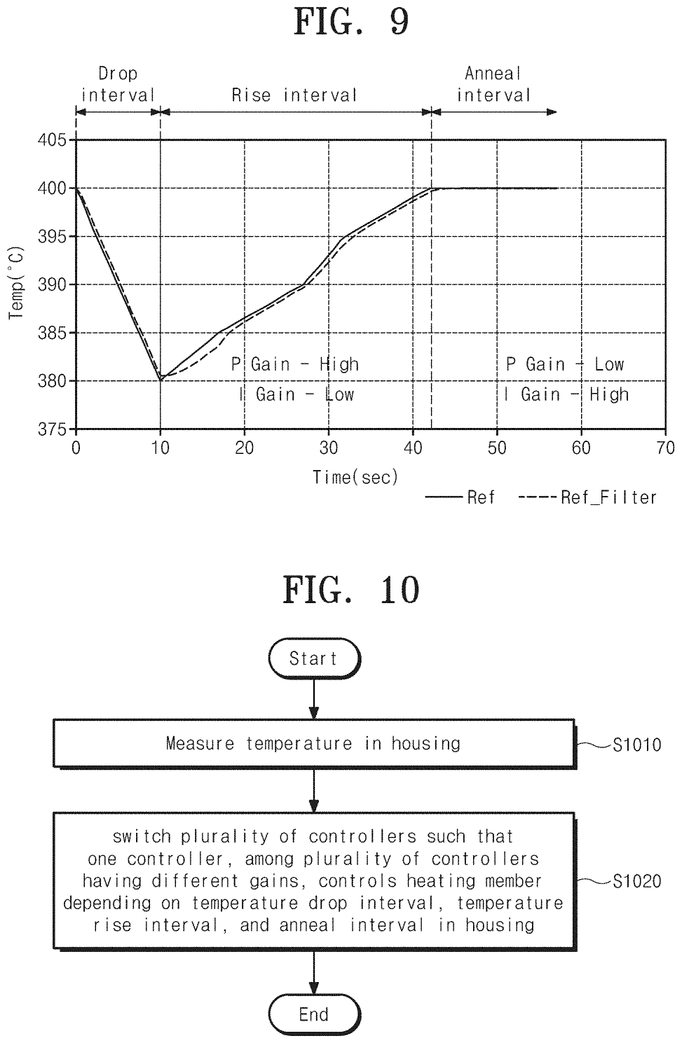

FIG. 10 is a flowchart illustrating a substrate treating method according to an embodiment of the inventive concept.

First, the temperature measurement member 910 measures the temperature in the housing 860 (S1010). Next, the control member 930 switches the plurality of controllers such that one controller, among the plurality of controllers having different gains, controls the heating member 830 depending on the temperature drop section, the temperature rise section, and the anneal section in the housing 860 (S1020). Here, the plurality of controllers may be a plurality of PID controllers having different PID gains. In step S1020, the PID controller having a relatively high P gain may be connected to the heating member 830 in the temperature drop section and the temperature rise section. Alternatively, the PID controller having a relatively high I or D gain may be connected to the heating member 830 in the anneal section. The temperature drop section, the temperature rise section, and the anneal section in the housing 860 may be determined by using the slope of temperature variation in the housing 860. Specifically, the section in which the slope of temperature variation is below the preset range may be determined to be the temperature drop section. The section in which the slope of temperature variation is above the preset range may be determined to be the temperature rise section. The section in which the slope of temperature variation is within the preset range may be determined to be the anneal section.

As described above, according to the various embodiments of the inventive concept, the control member switches the plurality of controllers to cause a controller having an appropriate gain to control the heating member depending on the temperature sections in the housing, thereby stably and accurately performing substrate temperature control.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The scope of the inventive concept should be determined by the technical idea of the claims, and it should be understood that the scope of the inventive concept is not limited to the literal description of the claims, but actually extends to the category of equivalents of technical value.

As described above, according to the various embodiments of the inventive concept, the plurality of controllers are switched such that a controller having an appropriate gain controls the heating member depending on the temperature sections in the housing. Thus, substrate temperature control may be stably and accurately performed.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a housing having a process space therein;
a plate configured to support the substrate in the housing;
a heating member provided in the plate and configured to heat the substrate;
a plurality of controllers configured to control the heating member, the controllers having different gains;
a temperature measurement member configured to measure temperature in the housing; and
a control member configured to switch the plurality of controllers to cause one of the plurality of controllers to control the heating member depending on a temperature drop section, a temperature rise section, and an anneal section in the housing.

2. The apparatus of claim 1, wherein the plurality of controllers are a plurality of PID controllers having different PID gains.

3. The apparatus of claim 2, wherein in the temperature drop section, the control member connects a PID controller having a relatively high P gain, among the plurality of PID controllers, to the heating member.

4. The apparatus of claim 2, wherein in the temperature rise section, the control member connects a PID controller having a relatively high P gain, among the plurality of PID controllers, to the heating member.

5. The apparatus of claim 2, wherein in the anneal section, the control member connects a PID controller having a relatively high I gain, among the plurality of PID controllers, to the heating member.

6. The apparatus of claim 2, wherein in the anneal section, the control member connects a PID controller having a relatively high D gain, among the plurality of PID controllers, to the heating member.

7. The apparatus of claim 1, wherein the control member determines the temperature drop section, the temperature rise section, and the anneal section by using a slope of temperature variation measured by the temperature measurement member.

8. The apparatus of claim 7, wherein the control member determines the temperature drop section when the slope of temperature variation is below a preset range, determines the temperature rise section when the slope of temperature variation is above the preset range, and determines the anneal section when the slope of temperature variation is within the preset range.

9. A bake apparatus comprising:
a housing having a process space therein;
a plate configured to support a substrate in the housing;
a heating member provided in the plate and configured to heat the substrate;
a plurality of PID controllers configured to control the heating member, the PID controllers having different PID gains;
a temperature measurement member configured to measure temperature in the housing; and
a control member configured to connect a PID controller having a relatively high P gain, among the plurality of PID controllers, to the heating member in a temperature drop section and a temperature rise section in the housing and connect a PID controller having a relatively high I or D gain, among the plurality of PID controllers, to the heating member in an anneal section in the housing.

10. The bake apparatus of claim 9, wherein the control member determines the temperature drop section, the temperature rise section, and the anneal section by using a reference profile stored in advance.

11. The bake apparatus of claim 10, wherein the control member determines the temperature drop section when a slope of temperature variation is below a preset range, determines the temperature rise section when the slope of temperature variation is above the preset range, and determines the anneal section when the slope of temperature variation is within the preset range.

12. A method for treating a substrate by controlling a heating member provided in a plate for supporting the substrate in a housing, the method comprising:
measuring temperature in the housing; and
switching a plurality of controllers having different gains to cause one of the plurality of controllers to control the heating member depending on a temperature drop section, a temperature rise section, and an anneal section in the housing.

13. The method of claim 12, wherein the plurality of controllers are a plurality of PID controllers having different PID gains.

14. The method of claim 13, wherein in the temperature drop section, a PID controller having a relatively high P gain, among the plurality of PID controllers, is connected to the heating member.

15. The method of claim 13, wherein in the temperature rise section, a PID controller having a relatively high P gain, among the plurality of PID controllers, is connected to the heating member.

16. The method of claim 13, wherein in the anneal section, a PID controller having a relatively high I gain, among the plurality of PID controllers, is connected to the heating member.

17. The method of claim 13, wherein in the anneal section, a PID controller having a relatively high D gain, among the plurality of PID controllers, is connected to the heating member.

18. The method of claim 12, wherein the temperature drop section, the temperature rise section, and the anneal section in the housing are determined by using a slope of temperature variation in the housing.

19. The method of claim 18, wherein the temperature drop section is determined when the slope of temperature variation is below a preset range, the temperature rise section is determined when the slope of temperature variation is above the preset range, and the anneal section is determined when the slope of temperature variation is within the preset range.
